(19) United States
(12) Patent Application Publication
(10) Pub. No.: US 2026/0206467 A1
(43) Pub. Date: Jul. 16, 2026

(54) DISPLAY DEVICE AND ELECTRONIC DEVICE

(71) Applicant: Samsung Display Co., Ltd., Yongin-si (KR)

(72) Inventors: Younjoon Kim, Yongin-si (KR); Sumin Choi, Yongin-si (KR); Sangkyung Kim, Yongin-si (KR); Jihyun Min, Yongin-si (KR)

(21) Appl. No.: 19/415,309

(22) Filed: Dec. 10, 2025

(30) Foreign Application Priority Data
Jan. 16, 2025 (KR) 10-2025-0006831

(51) Int. Cl. H10K 59/80

(52) U.S. Cl. CPC H10K 59/874; H10K 59/873

(57) ABSTRACT

A display device includes: a substrate having a display area and a peripheral area; a light-emitting diode on the substrate in the display area; a first infiltration barrier pattern on the substrate in the peripheral area; and a first dam pattern on the first infiltration barrier pattern. The first dam pattern includes an organic layer covering the first infiltration barrier pattern.

### CROSS-REFERENCE TO RELATED APPLICATION

The present application claims priority to and the benefit of Korean Patent Application No. 10-2025-0006831, filed on January 16, 2025, in the Korean Intellectual Property Office, the entire disclosure of which is incorporated herein by reference.

### BACKGROUND

### 1. Field

Aspects of embodiments of the present disclosure relate to a display device and an electronic device including the display device.

### 2. Description of the Related Art

Display devices visually display data. Such display devices may each include a substrate having a display area and a peripheral area. A plurality of pixels may be arranged in the display area. Thin-film transistors respectively corresponding to the pixels and light-emitting diodes electrically connected to the thin-film transistors may be placed in the display area. Various wires configured to transmit electrical signals to the display area, drivers, controllers, and the like may be placed in the peripheral area. Recently, display devices have been widely used. Accordingly, various designs have been made to improve the quality of display devices.

### SUMMARY

Infiltration barrier patterns may be arranged in a peripheral area of a display device to prevent foreign materials (e.g., moisture) from infiltrating from the outside of the display device towards a display area. The infiltration barrier patterns may directly block the introduction of foreign materials into the display device or may extend the path through which the foreign materials must take to infiltrate. Because of a step difference formed by the infiltration barrier patterns, cracks may appear in an inorganic layer arranged on the infiltration barrier patterns. Foreign materials (e.g., moisture) may infiltrate the display device through such cracks in the inorganic layer. Therefore, according to embodiments of the present disclosure, infiltration barrier patterns that may prevent the infiltration of foreign materials (e.g., moisture) while not causing cracks in the inorganic layer are provided.

Additional aspects and features of the present disclosure will be set forth, in part, in the description that follows and, in part, will be apparent from the description or may be learned by practice of the presented embodiments of the present disclosure.

According to an embodiment of the present disclosure, a display device includes a substrate having a display area and a peripheral area, a light-emitting diode on the substrate in the display area, a first infiltration barrier pattern on the substrate in the peripheral area, and a first dam pattern on the first infiltration barrier pattern. The first dam pattern includes an organic layer covering the first infiltration barrier pattern.

In an embodiment, the display device may further include a second infiltration barrier pattern on the substrate and spaced apart from the first infiltration barrier pattern, and a second dam pattern covering the second infiltration barrier pattern.

In an embodiment, the display device may further include an inorganic insulating layer between the first infiltration barrier pattern and the substrate, and an encapsulation layer arranged on the first dam pattern. Tthe encapsulation layer may be spaced apart from the first infiltration barrier pattern and the second infiltration barrier pattern.

In an embodiment, the encapsulation layer may directly contact the inorganic insulating layer in a region between the first dam pattern and the second dam pattern.

In an embodiment, the second dam pattern may further include an organic layer under the second infiltration barrier pattern.

In an embodiment, the display device may further include a third infiltration barrier. The organic layer of the first dam pattern may extend to the display area, and the third infiltration barrier pattern may be under the organic layer and spaced apart from the first infiltration barrier pattern.

In an embodiment, the first infiltration barrier pattern may include a first layer, a second layer on the first layer, and a third layer on the second layer, and at least one of the first layer, the second layer, and the third layer may include a material that is different from that of another one of the first layer, the second layer, and the third layer.

In an embodiment, a side surface of the second layer may be on a same plane as a side surface of the third layer.

In an embodiment, the display device may further include a voltage supply line extending in a first direction and configured to supply a voltage to the light-emitting diode, and the first infiltration barrier pattern may be a portion of the voltage supply line protruding in a second direction crossing the first direction.

In an embodiment, the first dam pattern may extend in the second direction.

According to another embodiment of the present disclosure, a display device includes a substrate having a display area and a peripheral area, an inorganic insulating layer on the substrate, a plurality of infiltration barrier patterns on the inorganic insulating layer in the peripheral area, a plurality of dam patterns covering the plurality of infiltration barrier patterns, and an encapsulation layer arranged on the plurality of dam patterns. The encapsulation layer directly contacts the inorganic insulating layer between two adjacent ones of the plurality of dam patterns.

In an embodiment, the encapsulation layer may be spaced apart from the plurality of infiltration barrier patterns.

In an embodiment, the plurality of dam patterns may include organic layers covering the plurality of infiltration barrier patterns, respectively.

In an embodiment, the organic layer of one of the plurality of dam patterns may cover two or more of the plurality of infiltration barrier patterns.

In an embodiment, one of the plurality of dam patterns may include an organic layer under a infiltration barrier pattern corresponding to the one of the plurality of dam patterns.

In an embodiment, one of the plurality of infiltration barrier patterns may include a first layer, a second layer on the first layer, and a third layer on the second layer, and at least one of the first layer, the second layer, and the third layer may include a material that is different from that of another of the first layer, the second layer, and the third layer.

In an embodiment, a side surface of the second layer may be on a same plane as a side surface of the third layer.

In an embodiment, the display device may further include a voltage supply line extending in a first direction and configured to supply power to the display area, wherein the plurality of infiltration barrier patterns may be portions of the voltage supply line protruding in a second direction crossing the first direction.

In an embodiment, the plurality of dam patterns may extend in the second direction and may be spaced apart from each other in the first direction.

According to another embodiment of the present disclosure, an electronic device includes a display device and a housing accommodating the display device. The display device includes a substrate having a display area and a peripheral area, a light-emitting diode on the substrate in the display area, a first infiltration barrier pattern on the substrate in the peripheral area, and a first dam pattern on the first infiltration barrier pattern. The first dam pattern includes an organic layer covering the first infiltration barrier pattern.

In an embodiment, the electronic device may further include a second infiltration barrier pattern on the substrate and spaced apart from the first infiltration barrier pattern, a second dam pattern covering the second infiltration barrier pattern, an inorganic insulating layer under the first infiltration barrier pattern and the second infiltration barrier pattern and on the substrate, and an encapsulation layer on the first dam pattern and the second dam pattern. The encapsulation layer is spaced apart from the first infiltration barrier pattern and the second infiltration barrier pattern.

In an embodiment, the electronic device may further include a voltage supply line extending in a first direction and configured to supply a voltage to the light-emitting diode, and the first infiltration barrier pattern may be a portion of the voltage supply line protruding in a second direction crossing the first direction.

### BRIEF DESCRIPTION OF THE DRAWINGS

The above and other aspects and features of embodiments of the present disclosure will be more apparent from the following description taken in conjunction with the accompanying drawings, in which:

FIG. 1 is a schematic plan view of an electronic device according to an embodiment;

FIG. 2 is a schematic plan view of a display device according to an embodiment;

FIG. 3 is a circuit diagram of a light-emitting diode in one pixel of a display device and a pixel circuit connected to the light-emitting diode according to an embodiment;

FIG. 4A is a cross-sectional view of a portion of a display device according to an embodiment;

FIG. 4B is a cross-sectional view of a portion of a display device according to an embodiment;

FIG. 5 is a schematic plan view of a portion of a display device according to an embodiment;

FIG. 6 is a cross-sectional view of a portion of a display device according to an embodiment;

FIG. 7 is a cross-sectional view of a portion of a display device according to an embodiment;

FIG. 8 is a cross-sectional view of a portion of a display device according to an embodiment;

FIG. 9 is a cross-sectional view of a portion of a display device according to an embodiment;

FIG. 10 is a schematic plan view of a portion of a display device according to an embodiment;

FIG. 11 is a cross-sectional view of a portion of a display device according to an embodiment;

FIG. 12 is a cross-sectional view of a portion of a display device according to an embodiment;

FIG. 13 is a cross-sectional view of a portion of a display device according to an embodiment; and

FIG. 14 is a schematic cross-sectional view illustrating one of a plurality of infiltration barrier patterns according to an embodiment.

### DETAILED DESCRIPTION

Reference will now be made, in detail, to embodiments, examples of which are illustrated in the accompanying drawings. In this regard, the illustrated embodiments may have different forms and should not be construed as being limited to the descriptions set forth herein. Accordingly, the embodiments are merely described below, by referring to the figures, to explain aspects and features of the present description.

As used herein, the term "and/or" includes any and all combinations of one or more of the associated listed items. Throughout the present disclosure, the expression "at least one of a, b, or c" indicates only a, only b, only c, both a and b, both a and c, both b and c, all of a, b, and c, or variations thereof.

Because the present disclosure allows for various changes and numerous embodiments, example embodiments will be shown in the drawings and described in detail in the written description. The attached drawings illustrating embodiments of the present disclosure are included to provide a sufficient understanding of aspects and features of the present disclosure. The present disclosure may, however, be embodied in many different forms and should not be construed as being limited to the embodiments set forth herein.

Hereinafter, one or more embodiments of the present disclosure will be described in detail with reference to the accompanying drawings. Like elements in the drawings denote like elements, and repeated descriptions thereof are omitted.

It will be understood that although the terms "first," "second," etc. may be used herein to describe various elements, these elements should not be limited by these terms, and these elements are only used to distinguish one element from another.

As used herein, the singular forms "a," "an," and "the" are intended to include the plural forms as well, unless the context clearly indicates otherwise.

It will be further understood that the terms "comprises" and/or "comprising" used herein specify the presence of stated features or elements, but do not preclude the presence or addition of one or more other features or elements.

It will be understood that when a layer, region, or element is referred to as being "formed on" another layer, region, or element, it can be directly or indirectly formed on the other layer, region, or element. That is, for example, intervening layers, regions, or elements may be present.

. As used herein, the terms “use,” “using,” and “used” may be considered synonymous with the terms “utilize,” “utilizing,” and “utilized,” respectively. As used herein, the terms "substantially," "about," and similar terms are used as terms of approximation and not as terms of degree, and are intended to account for the inherent variations in measured or calculated values that would be recognized by those of ordinary skill in the art.

Sizes of elements in the drawings may be exaggerated for convenience of explanation. In other words, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or component is referred to as being connected to another layer, region, or component, it can be directly or indirectly connected to the other layer, region, or component. For example, when a layer, region, or component is referred to as being electrically connected to another layer, region, or component, it can be directly or indirectly electrically connected to the other layer, region, or component.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of "1.0 to 10.0" is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

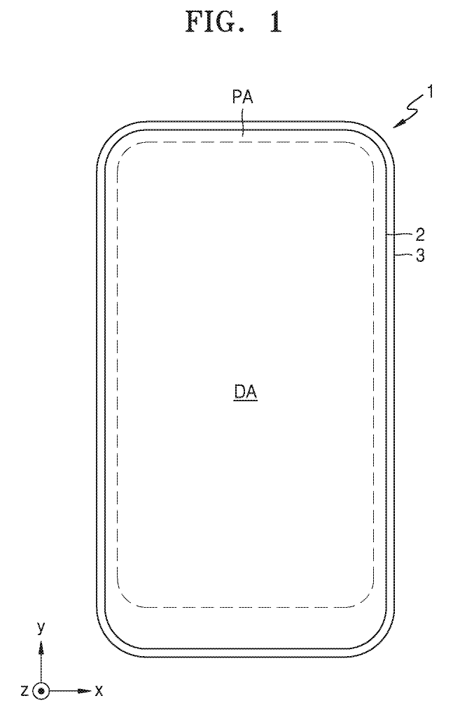

FIG. 1 is a schematic plan view of an electronic device 1 according to an embodiment.

The electronic device 1 may include a display device 2 and a housing 3. In an embodiment, the display device 2 may be accommodated in the housing 3.

In an embodiment, the electronic device 1 may be used as, for example, a portable electric device, such as a mobile phone, a smartphone, a tablet Personal Computer (PC), a mobile communication terminal, a personal digital assistant, an e-book terminal, a Portable Multimedia Player (PMP), a navigation device, or an Ultra-Mobile PC (UMPC), a television (TV), a laptop, a monitor, a billboard, an Internet of Things (IoT) device, and the like. In an embodiment, the electronic device 1 may be used as a wearable device, such as a smartwatch, a watch phone, an eyewear display, or a head-mounted display (HMD). In an embodiment, the electronic device 1 may be used as a display in an instrument cluster of a vehicle, a Center Information Display (CID) mounted on a center fascia or a dashboard of a vehicle, a room mirror display replacing side-view mirrors of a vehicle, or a car headrest monitor for rear-seat entertainment. The display device 2 may be included in the electronic device 1 as a component for displaying moving images or still images in various products as described above.

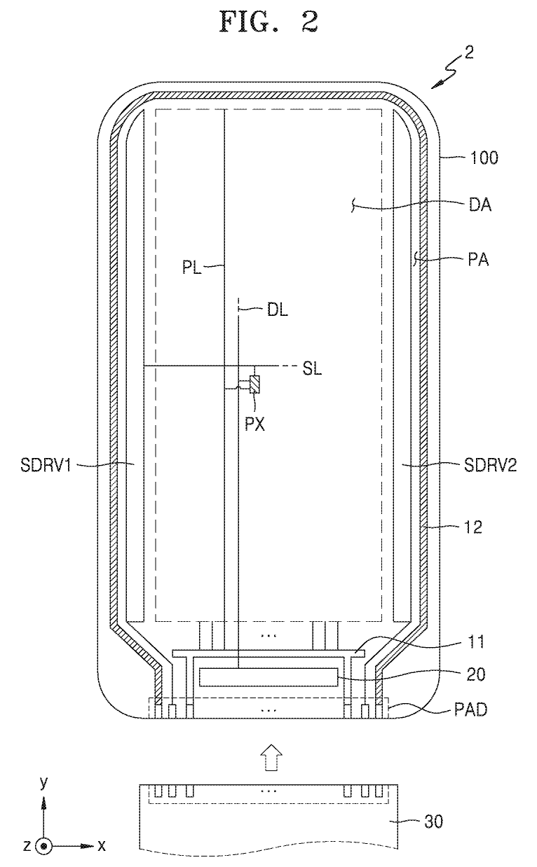

The display device 2 may have a display area DA and a peripheral area PA on the outer side (or the periphery) of the display area DA. Because the display device 2 may include a substrate (100, see, e.g., FIG. 2), it may be understood that the substrate 100 has (or defines) the display area DA and the peripheral area PA. Alternatively, it may be understood that the display area DA and the peripheral area PA are defined in the substrate 100.

The display area DA is an area at where images are displayed, and a plurality of pixels may be arranged therein. The display area DA may have one of various shapes, such as a circle, an oval, a polygon, and other shapes. FIG. 1 illustrates an embodiment in which the display area DA has a substantially rectangular shape with rounded edges.

The peripheral area PA may be arranged on the outer side of (e.g., around a periphery of) the display area DA. The peripheral area PA may at least partially surround (e.g., surround in a plan view) the display area DA.

Hereinafter, the display device 2 is described as an organic light-emitting display device, but the display device 2 is not limited thereto. As another embodiment, the display device 2 may be, for example, an inorganic light-emitting display device (or an inorganic EL display device) or a quantum dot light-emitting display device. For example, an emission layer of a display element (e.g., a light-emitting diode) included in the display device 2 may include an organic material, an inorganic material, quantum dots, both an organic material and quantum dots, or both an inorganic material and quantum dots.

FIG. 2 is a schematic plan view of the display device 2 according to an embodiment.

Referring to FIG. 2, the display device 2 may include the substrate 100. Various components included in the display device 2 may be arranged on the substrate 100. The substrate 100 may have the display area DA and the peripheral area PA on the outer side of the display area DA. In the present specification, the description of a component being arranged in the display area DA indicates that the component is arranged on the substrate 100 in the display area DA or overlaps the display area DA of the substrate 100. Similarly, in the present specification, the description of a component being arranged in the peripheral area PA indicates that the component is arranged on the substrate 100 in the peripheral area PA or overlaps the peripheral area PA of the substrate 100.

In the display area DA, a plurality of pixels PX may be arranged. Each pixel PX may include a light-emitting diode as a display element. Each pixel PX may include a pixel circuit configured to drive the light-emitting diode. The pixel PX may emit, for example, red light, green light, blue light, or white light. In the present specification, the term "pixel" may be understood to also refer to "sub-pixels" grouped together to form a single pixel.

The pixel circuits of the pixels PX may be connected to signal lines and/or voltage lines configured to control the on/off states and luminance of the light-emitting diodes. In an embodiment, the signal lines may include a scan line extending in a first direction (e.g., an x-axis direction) and a data line DL extending in a second direction (e.g., a y-axis direction). In an embodiment, the voltage line may include a driving voltage line PL.

The peripheral area PA may be a non-display area where no images are displayed. The peripheral area PA may entirely surround (e.g., may extend entirely around) the display area DA. Outer circuits for driving the pixels PX may be arranged in the peripheral area PA. For example, a first scan driver SDRV1, a second scan driver SDRV2, a data driver 20, a terminal portion PAD, a driving voltage supply line 11, and a common voltage supply line 12 may be arranged in the peripheral area PA.

The first scan driver SDRV1 may be configured to apply a scan signal to the pixel circuits of the pixels PX through the scan line SL. The second scan driver SDRV2 may be located on the opposite side of the first scan driver SDRV1 with respect to the display area DA and may be substantially parallel to the first scan driver SDRV1. Some of the pixel circuits of the pixels PX arranged in the display area DA may be electrically connected to the first scan driver SDRV1, while others thereof may be electrically connected to the second scan driver SDRV2.

The data driver 20 may include an integrated circuit (e.g., an integrated circuit chip) configured to drive the display device 2. Such an integrated circuit may be a data driving integrated circuit configured to generate a data signal, but embodiments are not limited thereto. The data driver 20 may include a plurality of terminals. The data driver 20 may be electrically connected to a printed circuit board 30, which is attached to one side of the display device 2, through terminals. In another embodiment, the data driver 20 may be arranged on the printed circuit board 30.

The terminal portion PAD may be arranged on one side of the substrate 100. The terminal portion PAD may not be covered by (e.g., may be exposed by or through) an insulating layer to be connected to the printed circuit board 30.

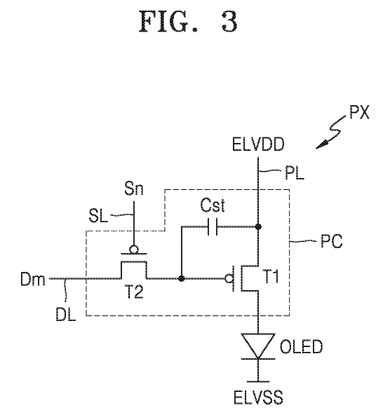

A controller may be arranged on the printed circuit board 30. The controller may generate control signals transmitted to the first scan driver SDRV1 and the second scan driver SDRV2. In addition, the controller may supply a driving voltage ELVDD to the driving voltage supply line 11 and a common voltage ELVSS to the common voltage supply line 12 (see, e.g., FIG. 3). The driving voltage ELVDD may be applied to the pixel circuits of the pixels PX through the driving voltage line PL connected to the driving voltage supply line 11. The common voltage ELVSS may be applied to an opposite electrode of the light-emitting diode connected to the common voltage supply line 12. The driving voltage supply line 11 may extend in the first direction (e.g., the x-axis direction) at the lower side of the display area DA. The common voltage supply line 12 may have a loop shape with one open side and, thus, may partially surround the display area DA. However, the present disclosure is not limited to the specific shapes of the driving voltage supply line 11 and the common voltage supply line 12.

The controller may generate data signals, and the generated data signals may be transmitted to the data line DL through the data driver 20. The data signals may be sequentially transmitted to the pixels PX in the same column through the data lines DL extending in the second direction (e.g., the y direction).

FIG. 3 is a schematic circuit diagram illustrating a light-emitting diode included in one pixel PX of a display device and a pixel circuit PC connected to the light-emitting diode according to an embodiment.

Referring to FIG. 3, the pixel circuit PC may be connected to a light-emitting diode, such as an organic light-emitting diode OLED, and enable the emission of the pixels PX. The pixel circuit PC may include a first transistor T1, a second transistor T2, and a storage capacitor Cst. In an embodiment, the first transistor T1 may be a driving transistor, and the second transistor T2 may be a switching transistor.

The second transistor T2 may be connected to the scan line SL and the data line DL. The second transistor T2 may be configured to transmit a data signal Dm, which is input through the data line DL, to the first transistor T1 in response to a scan signal Sn that is input through the scan line SL.

The storage capacitor Cst may be connected to the second transistor T2 and the driving voltage line PL. The storage capacitor Cst may store a voltage corresponding to the difference between a voltage transmitted from the second transistor T2 and the driving voltage ELVDD provided to the driving voltage line PL.

The first transistor T1 may be connected to the driving voltage line PL and the storage capacitor Cst. The first transistor T1 may control a driving current flowing through the organic light-emitting diode OLED from the driving voltage line PL according to the voltage stored in the storage capacitor Cst. The organic light-emitting diode OLED may emit light having a brightness according to the driving current.

The pixel circuit PC is not limited to the number of thin-film transistors, the number of storage capacitors, and circuit design described with reference to FIG. 3, and the numbers thereof and the circuit design may be variously modified.

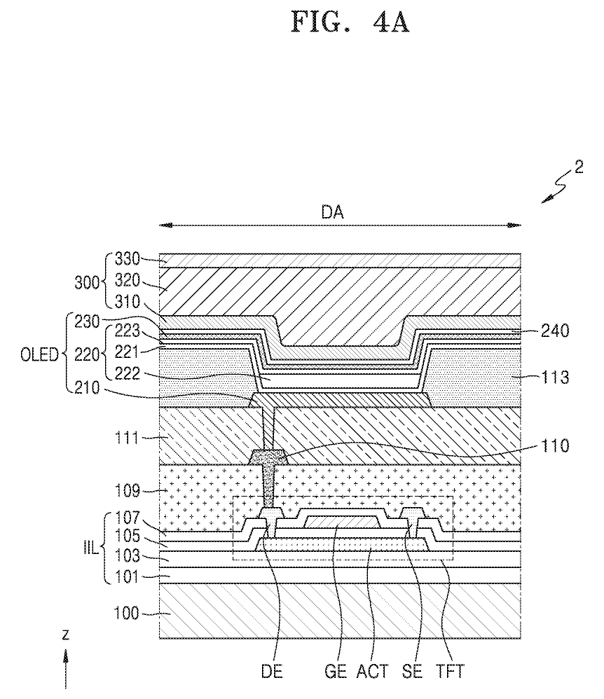

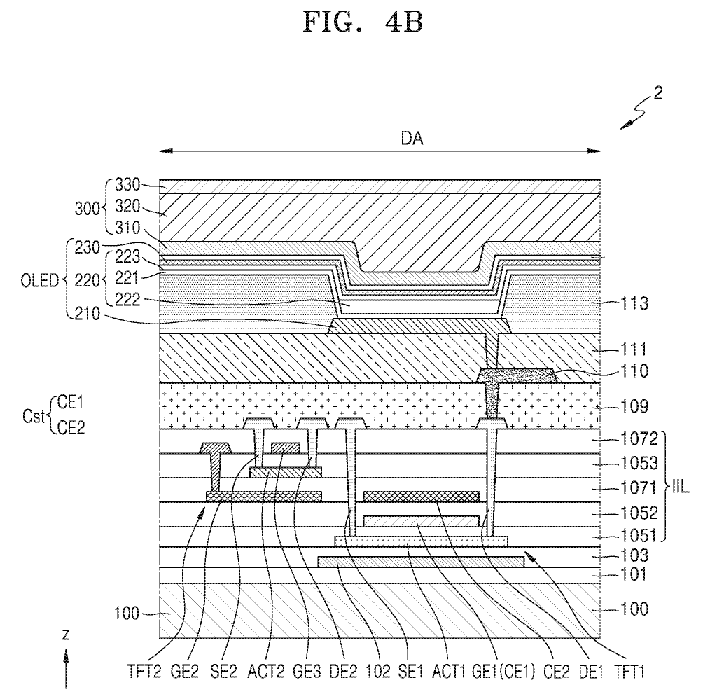

FIG. 4A is a cross-sectional view of a portion of the display area DA of the display device 2 according to an embodiment.

Referring to FIG. 4A, an inorganic insulating layer IIL, a thin-film transistor TFT, and an organic light-emitting diode OLED may be arranged on the substrate 100. The organic light-emitting diode OLED may be electrically connected to the thin-film transistor TFT. The inorganic insulating layer IIL may include a plurality of layers, and components of the thin-film transistor TFT may be arranged between individual layers of the inorganic insulating layer IIL. In an embodiment, the inorganic insulating layer IIL may include a barrier layer 101, a buffer layer 103, a gate insulating layer 105, and an interlayer insulating layer 107.

The barrier layer 101 and the buffer layer 103 may be arranged on the substrate 100. The barrier layer 101 and the buffer layer 103 may flatten (e.g., may planarize) the upper surface of the substrate 100 and may protect the substrate 100. The barrier layer 101 and the buffer layer 103 may each include an inorganic insulating material. For example, the barrier layer 101 and the buffer layer 103 may each include at least one inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may have a single-layer structure or a multilayer structure.

The thin-film transistor TFT may be arranged on the buffer layer 103. The thin-film transistor TFT may include an active layer ACT, a gate electrode GE, a source electrode SE, and a drain electrode DE. The thin-film transistor TFT may be connected to the organic light-emitting diode OLED and may drive the same. In an embodiment, the thin-film transistor TFT may be the first transistor T1 described above with reference to FIG. 3.

An active layer ACT may be arranged on the buffer layer 103. The active layer ACT may have a drain area overlapping a drain electrode DE, a source area overlapping a source electrode SE, and a channel area between the drain area and the source area. The drain area and the source area may each be an area doped with impurities (e.g., dopants).

The gate insulating layer 105 may be arranged on the active layer ACT. The gate insulating layer 105 may include an inorganic insulating material. For example, the gate insulating layer 105 may include at least one inorganic insulating material, such as SiO₂, SiNₓ, SiON, Al₂O₃, TiO₂, Ta₂O₅, HfO_{2,} or ZnO₂, and may have a single-layer structure or a multilayer structure. In an embodiment, the gate insulating layer 105 may entirely cover the active layer ACT, as shown in FIG. 4A. In another embodiment, the gate insulating layer 105 may be patterned to cover only some portions of the active layer ACT (e.g., a portion overlapping the gate electrode GE, that is, the channel area).

The gate electrode GE may be arranged on the gate insulating layer 105. The gate electrode GE may overlap the active layer ACT. For example, the gate electrode GE may overlap the channel area of the active layer ACT. The gate electrode GE may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may have a single-layer structure or a multilayer structure.

The interlayer insulating layer 107 may be arranged to cover the gate electrode GE. The interlayer insulating layer 107 may include an inorganic insulating material. For example, the interlayer insulating layer 107 may include at least one inorganic insulating material, such as SiO₂, SiNₓ, SiON, Al₂O₃, TiO₂, Ta₂O₅, HfO_{2,} or ZnO₂, and may have a single-layer structure or a multilayer structure.

The gate insulating layer 105 and the interlayer insulating layer 107 may have a contact hole (e.g., a contact opening) overlapping the source area and a contact hole (e.g., a contact opening) overlapping the drain area of the active layer ACT. The source electrode SE and the drain electrode DE may be arranged on the interlayer insulating layer 107. The source electrode SE may overlap the source area of the active layer ACT, and the drain electrode DE may overlap the drain area of the active layer ACT. The source electrode SE and the drain electrode DE may be connected to the active layer ACT through the contact holes formed in the gate insulating layer 105 and the interlayer insulating layer 107, respectively.

A first organic insulating layer 109 and a second organic insulating layer 111 may be sequentially arranged on the interlayer insulating layer 107. The first organic insulating layer 109 and the second organic insulating layer 111 may each have a contact hole (e.g., a contact opening) overlapping the drain electrode DE. A contact metal 110 may be arranged on the first organic insulating layer 109. The contact metal 110 may be connected to the drain electrode DE through the contact hole defined in the first organic insulating layer 109.

The first organic insulating layer 109 and the second organic insulating layer 111 may include an organic insulating material, for example, a general-purpose polymer, such as benzocyclobutene (BCB), polyimide, hexamethyldisiloxane (HMDSO), polymethylmethacrylate (PMMA), or polystyrene, a polymer derivative having a phenol-based group, an acryl-based polymer, an imide-based polymer, an aryl-ether-based polymer, an amide-based polymer, a fluorine-based polymer, a p-xylene-based polymer, or a vinyl alcohol-based polymer, and may have a single-layer structure or a multilayer structure.

The organic light-emitting diode OLED may be arranged on the second organic insulating layer 111. The organic light-emitting diode OLED may include a pixel electrode 210, an intermediate layer 220, and an opposite electrode 230.

The pixel electrode 210 may be arranged on the second organic insulating layer 111. The pixel electrode 210 may be connected to the contact metal 110 through the contact hole in the second organic insulating layer 111. The pixel electrode 210 may be connected to the drain electrode DE of the thin-film transistor TFT through the contact metal 110.

In an embodiment, the pixel electrode 210 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 210 may include a reflection film including Ag, Mg, Al, Pt, Pd, Au, Ni, Nd, Ir, Cr, or a compound thereof. The structure and materials of the pixel electrode 210 are not limited thereto and may vary.

A pixel-defining layer 113 may be arranged on the second organic insulating layer 111. The pixel-defining layer 113 may cover an edge (or an edge portion) of the pixel electrode 210. For example, the pixel-defining layer 113 may have an opening to expose the central portion of the pixel electrode 210. The size and shape of the emission area of the organic light-emitting diode OLED may be determined by the opening in the pixel-defining layer 113.

The intermediate layer 220 may be arranged on the pixel electrode 210. The intermediate layer 220 may include a first functional layer 221 and a second functional layer 223 that are arranged on the pixel-defining layer 113, and an emission layer 222 arranged in the opening in the pixel-defining layer 113. In an embodiment, the first functional layer 221 may be arranged on the pixel-defining layer 113, the emission layer 222 may be arranged on the first functional layer 221 within the opening in the pixel-defining layer 113, and the second functional layer 223 may be arranged on the first functional layer 221 to cover the emission layer 222. For example, the emission layer 222 may be arranged in the opening in the pixel-defining layer 113 and between the first functional layer 221 and the second functional layer 223.

The emission layer 222 may include an organic emission layer including a low-molecular-weight material or a high-molecular-weight material. The first functional layer 221 may include (or may be) an Electron Transport Layer (ETL) and/or an Electron Injection Layer (EIL). The second functional layer 223 may include (or may be) a Hole Transport Layer (HTL) and/or a Hole Injection Layer (HIL). In some embodiments, the first functional layer 221 or the second functional layer 223 may be omitted. In an embodiment, the positions of the first functional layer 221 and the second functional layer 223 may be interchanged.

The opposite electrode 230 may be arranged on the intermediate layer 220. For example, the opposite electrode 230 may be arranged on the second functional layer 223. The opposite electrode 230 may be arranged to entirely cover the intermediate layer 220. In an embodiment, the opposite electrode 230 may include a conductive material having a low work function. For example, the opposite electrode 230 may include a transparent (translucent) layer including Ag, Mg, Al, Pt, Pd, Au, Ni, Nd, Ir, Cr, lithium (Li), calcium (Ca), or an alloy thereof. In another embodiment, the opposite electrode 230 may include a layer including ITO, IZO, ZnO, or In₂O₃ on the transparent (or translucent) layer including the above material.

A capping layer 240 may be arranged on the opposite electrode 230. The capping layer 240 may have a lower refractive index than the opposite electrode 230 and may improve the light efficiency by reducing the proportion of light from the emission layer 222 that is totally internally reflected and not emitted outwardly.

The capping layer 240 may include an organic capping layer including an organic material, an inorganic capping layer including an inorganic material, and a compound capping layer including both an organic material and an inorganic material. For example, the capping layer 240 may include a carbocyclic compound, a heterocyclic compound, an amine group-containing compound, porphine derivatives, phthalocyanine derivatives, naphthalocyanine derivatives, alkali metal complexes, alkali earth metal complexes, or an arbitrary combination thereof. In some embodiments, the capping layer 240 may include an inorganic material, such as ZnO₂, TiO₂, zirconium oxide (ZrO₂), nitrogen oxide (NO), niobium oxide (Nb₂O₅), Ta₂O₅, tin oxide (SnO₂), nickel oxide (NiO), indium nitride (InN), or gallium nitride (GaN). However, the materials that may be used to form the capping layer 240 are not limited thereto, and the capping layer 240 may include other materials.

An encapsulation layer 300 may be arranged on the capping layer 240. The encapsulation layer 300 may include at least one inorganic encapsulation layer and at least one organic encapsulation layer. In an embodiment, the encapsulation layer 300 may include a first inorganic encapsulation layer 310, a second inorganic encapsulation layer 330, and an organic encapsulation layer 320 therebetween. The first inorganic encapsulation layer 310 and the second inorganic encapsulation layer 330 may each include at least one inorganic insulating material, such as SiO₂, SiNₓ, SiON, Al₂O₃,TiO₂,Ta₂O₅, HfO₂, or ZnO₂. The organic encapsulation layer 320 may include a polymer-based material. Examples of the polymer-based material may include silicon-based resin, acrylic resin, epoxy-based resin, polyimide, polyethylene, and the like.

FIG. 4B is a cross-sectional view of a portion of the display area DA of the display device 2 according to an embodiment.

Referring to FIG. 4B, an inorganic insulating layer IIL, a first thin-film transistor TFT1, a second thin-film transistor TFT2, and an organic light-emitting diode OLED may be arranged on the substrate 100. The organic light-emitting diode OLED may be electrically connected to the first thin-film transistor TFT1. The inorganic insulating layer IIL may include a plurality of layers, and components of the first thin-film transistor TFT1 and the second thin-film transistor TFT2 may be arranged between respective layers of the inorganic insulating layer IIL. In an embodiment, the inorganic insulating layer IIL may include a barrier layer 101, a buffer layer 103, a first gate insulating layer 1051, a second gate insulating layer 1052, a first interlayer insulating layer 1071, a third gate insulating layer 1053, and a second interlayer insulating layer 1072.

The characteristics of the barrier layer 101 and the buffer layer 103 are described above with reference to FIG. 4A. A conductive layer 102 may be arranged between the barrier layer 101 and the buffer layer 103. The conductive layer 102 may overlap the first thin-film transistor TFT1. In an embodiment, the conductive layer 102 may act as an anti-reflection layer. In an embodiment, the conductive layer 102 may act as, for example, a wire configured to supply a driving voltage to the first thin-film transistor TFT1.

The first thin-film transistor TFT1 may be arranged on the buffer layer 103. The first thin-film transistor TFT1 may include a first active layer ACT1, a first gate electrode GE1, a first source electrode SE1, and a first drain electrode DE1. The first thin-film transistor TFT1 may be connected to the organic light-emitting diode OLED and may drive the same. In an embodiment, the first thin-film transistor TFT1 may be the first transistor T1 described above with reference to FIG. 3.

The first active layer ACT1 may be arranged on the buffer layer 103. The first active layer ACT1 may have a drain area overlapping the first drain electrode DE1, a source area overlapping the first source electrode SE1, and a channel area between the drain area and the source area. The drain area and the source area of the first active layer ACT1 may each be an area doped with impurities (e.g., dopants).

The first gate insulating layer 1051 may be arranged on the first active layer ACT1. The first gate insulating layer 1051 may include an inorganic insulating material. For example, the first gate insulating layer 1051 may include at least one inorganic insulating material, such as SiO₂, SiNₓ, SiON, Al₂O₃, TiO₂, Ta₂O₅, HfO_{2,} or ZnO₂, and may have a single-layer structure or a multilayer structure. In an embodiment, the first gate insulating layer 1051 may entirely cover the first active layer ACT1 as shown in FIG. 4B. In another embodiment, the first gate insulating layer 1051 may be patterned to cover only some portions of the first active layer ACT1 (e.g., a portion overlapping the first gate electrode GE1, that is, the channel area).

The first gate electrode GE1 may be arranged on the first gate insulating layer 1051. The first gate electrode GE1 may overlap the first active layer ACT1. For example, the first gate electrode GE1 may overlap the channel area of the first active layer ACT1. The first gate electrode GE1 may include at least one of Al, Pt, Pd, Ag, Mg, Au, Ni, Nd, Ir, Cr, Ca, Mo, Ti, W, and/or Cu and may have a single-layer structure or a multilayer structure.

The storage capacitor Cst may include a first capacitor electrode CE1 and a second capacitor electrode CE2. The first capacitor electrode CE1 may be arranged on the same layer as the first gate electrode GE1. The first capacitor electrode CE1 may be arranged on the first gate insulating layer 1051. In an embodiment, the first capacitor electrode CE1 and the first gate electrode GE1 may be integrally formed as shown in FIG. 4B. In an embodiment, the first capacitor electrode CE1 and the first gate electrode GE1 may include the same material. In an embodiment, the first capacitor electrode CE1 and the first gate electrode GE1 may be formed through the same process. However, embodiments are not limited thereto, and the first capacitor electrode CE1 and the first gate electrode GE1 may be separately formed.

The second gate insulating layer 1052 may be arranged to cover the first gate electrode GE1 and the first capacitor electrode CE1. The second gate insulating layer 1052 may include an inorganic insulating material. For example, the second gate insulating layer 1052 may include at least one inorganic insulating material, such as SiO₂, SiNₓ, SiON, Al₂O₃, TiO₂, Ta₂O₅, HfO_{2,} or ZnO₂, and may have a single-layer structure or a multilayer structure.

The second thin-film transistor TFT2 may be arranged on the second gate insulating layer 1052. The second thin-film transistor TFT2 may include a second active layer ACT2, a second gate electrode GE2, a third gate electrode GE3, a second source electrode SE2, and a second drain electrode DE2. In an embodiment, the second thin-film transistor TFT2 may be the second transistor T2 described above with reference to FIG. 3.

The second gate electrode GE2 may be arranged on the second gate insulating layer 1052. The second gate electrode GE2 may be arranged under the second active layer ACT2. The second gate electrode GE2 may be a lower gate electrode of the second thin-film transistor TFT2. The second gate electrode GE2 may overlap the second active layer ACT2. The second gate electrode GE2 may include at least one of Al, Pt, Pd, Ag, Mg, Au, Ni, Nd, Ir, Cr, Ca, Mo, Ti, W, and/or Cu and may have a single-layer structure or a multilayer structure.

The second capacitor electrode CE2 may be arranged on the second gate insulating layer 1052. The second capacitor electrode CE2 may overlap the first capacitor electrode CE1. The second capacitor electrode CE2 may be arranged on the same layer as the second gate electrode GE2. In an embodiment, the second capacitor electrode CE2 and the second gate electrode GE2 may include the same material. In an embodiment, the second capacitor electrode CE2 and the second gate electrode GE2 may be formed through the same process.

The first interlayer insulating layer 1071 may be arranged to cover the second gate electrode GE2 and the second capacitor electrode CE2. The first interlayer insulating layer 1071 may include an inorganic insulating material. For example, the first interlayer insulating layer 1071 may include at least one inorganic insulating material, such as SiO₂, SiNₓ, SiON, Al₂O₃, TiO₂, Ta₂O₅, HfO_{2,} or ZnO₂, and may have a single-layer structure or a multilayer structure.

The second active layer ACT2 may be arranged on the second interlayer insulating layer 1072. The second active layer ACT2 may have a drain area overlapping the second drain electrode DE2, a source area overlapping the second source electrode SE2, and a channel area between the drain area and the source area. The drain area and the source area of the second active layer ACT2 may each be an area doped with impurities (e.g., dopants).

The third gate insulating layer 1053 may be arranged to cover the second active layer ACT2. The third gate insulating layer 1053 may include an inorganic insulating material. For example, the third gate insulating layer 1053 may include at least one inorganic insulating material, such as SiO₂, SiNₓ, SiON, Al₂O₃, TiO₂, Ta₂O₅, HfO_{2,} or ZnO₂, and may have a single-layer structure or a multilayer structure.

The third gate electrode GE3 may be arranged on the third gate insulating layer 1053. The third gate electrode GE3 may be an upper gate electrode of the second thin-film transistor TFT2. The third gate electrode GE3 may overlap the second active layer ACT2. The third gate electrode GE3 may include at least one of Al, Pt, Pd, Ag, Mg, Au, Ni, Nd, Ir, Cr, Ca, Mo, Ti, W, and/or Cu and may have a single-layer structure or a multilayer structure.

The second interlayer insulating layer 1072 may be arranged to cover the third gate electrode GE3. The second interlayer insulating layer 1072 may include an inorganic insulating material. For example, the second interlayer insulating layer 1072 may include at least one inorganic insulating material, such as SiO₂, SiNₓ, SiON, Al₂O₃, TiO₂, Ta₂O₅, HfO_{2,} or ZnO₂, and may have a single-layer structure or a multilayer structure.

The first source electrode SE1, the first drain electrode DE1, the second source electrode SE2, and the second drain electrode DE2 may be arranged on the second interlayer insulating layer 1072. In an embodiment, the first source electrode SE1, the first drain electrode DE1, the second source electrode SE2, and the second drain electrode DE2 may be arranged on the same layer and include the same material. In an embodiment, the first source electrode SE1, the first drain electrode DE1, the second source electrode SE2, and the second drain electrode DE2 may be formed through the same process.

The first source electrode SE1 may be connected to the source area of the first active layer ACT1 through the contact hole (e.g., the contact opening) formed in the first gate insulating layer 1051 to the third gate insulating layer 1053, the first interlayer insulating layer 1071, and the second interlayer insulating layer 1072. The first drain electrode DE1 may be connected to the drain area of the first active layer ACT1 through the contact hole (e.g., the contact opening) formed in the first gate insulating layer 1051 to the third gate insulating layer 1053, the first interlayer insulating layer 1071, and the second interlayer insulating layer 1072.

The second source electrode SE2 may be connected to the source area of the second active layer ACT2 through the contact hole (e.g., the contact opening) formed in the second interlayer insulating layer 1072 and the third gate insulating layer 1053. The second drain electrode DE2 may be connected to the drain area of the second active layer ACT2 through the contact hole (e.g., the contact opening) formed in the second interlayer insulating layer 1072 and the third gate insulating layer 1053.

The first organic insulating layer 109, the contact metal 110, the second organic insulating layer 111, the organic light-emitting diode OLED, the capping layer 240, and the encapsulation layer 300 may be sequentially arranged on the first source electrode SE1, the first drain electrode DE1, the second source electrode SE2, and the second drain electrode DE2. The characteristics of the first organic insulating layer 109, the contact metal 110, the second organic insulating layer 111, the organic light-emitting diode OLED, the capping layer 240, and the encapsulation layer 300 are described above with reference to FIG. 4A.

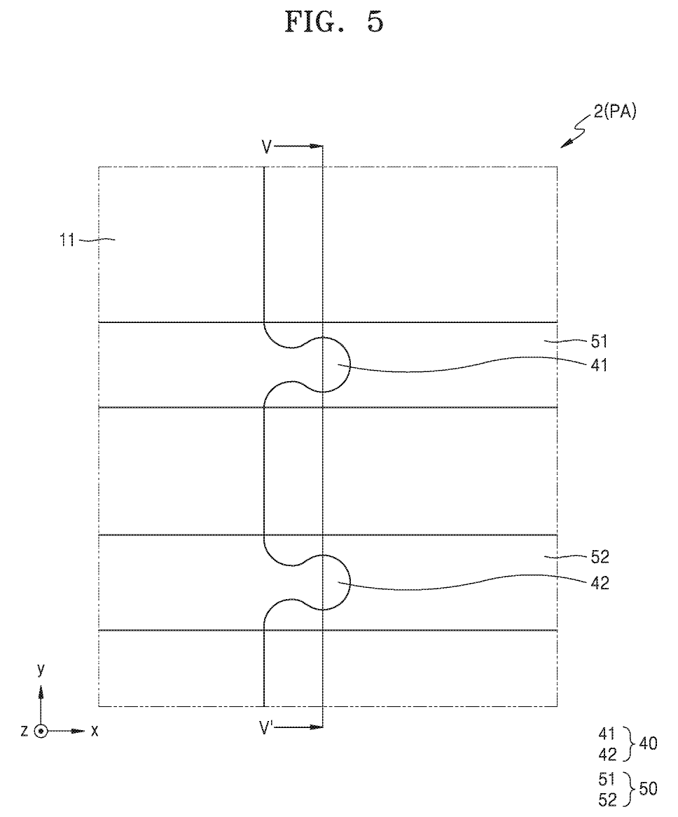

FIG. 5 is a schematic plan view of a portion of the peripheral area PA of the display device 2 according to an embodiment.

Referring to FIG. 5, the display device 2 may include a plurality of infiltration barrier patterns 40 and a plurality of dam patterns 50 arranged in the peripheral area PA.

In an embodiment, the infiltration barrier pattern 40 may include a first infiltration barrier pattern 41 and a second infiltration barrier pattern 42. In an embodiment, the infiltration barrier patterns 40 may extend in the first direction (e.g., the x-axis direction). In an embodiment, the infiltration barrier patterns 40 may be aligned in the second direction (e.g., the y-axis direction). For example, the first infiltration barrier pattern 41 and the second infiltration barrier pattern 42 may extend in the first direction (e.g., the x-axis direction) and may be aligned in the second direction (e.g., the y-axis direction). In an embodiment, the first infiltration barrier pattern 41 may be arranged in the +y direction from the second infiltration barrier pattern 42.

In an embodiment, the dam patterns 50 may include a first dam pattern 51 and a second dam pattern 52. In an embodiment, the dam patterns 50 may extend in the first direction (e.g., the x-axis direction). In an embodiment, the dam patterns 50 may be aligned in the second direction (e.g., the y-axis direction). For example, the first dam pattern 51 and the second dam pattern 52 may extend in the first direction (e.g., the x-axis direction) and may be aligned in (e.g., may be adjacent to each other in) the second direction (e.g., the y-axis direction). In an embodiment, the first dam pattern 51 may be arranged in the +y direction of the second dam pattern 52.

The infiltration barrier patterns 40 may overlap the dam patterns 50. In an embodiment, the first infiltration barrier pattern 41 may overlap the first dam pattern 51. For example, the first dam pattern 51 may cover the first infiltration barrier pattern 41. In an embodiment, the second infiltration barrier pattern 42 may overlap the second dam pattern 52. For example, the second dam pattern 52 may cover the second infiltration barrier pattern 42.

The infiltration barrier patterns 40 may be portions of the driving voltage supply line 11. The driving voltage supply line 11 may generally extend in the second direction (e.g., the y-axis direction), and the infiltration barrier patterns 40 may be portions of the driving voltage supply line 11 protruding in the first direction (e.g., the x-axis direction). For example, the first infiltration barrier pattern 41 and the second infiltration barrier pattern 42 may be portions of the driving voltage supply line 11 protruding in the first direction (e.g., the x-axis direction). However, one or more embodiments are not limited thereto, and in another embodiment, the infiltration barrier patterns 40 may be portions of other lines (e.g., the common voltage supply line 12 (see, e.g., FIG. 2)).

In an embodiment, the infiltration barrier patterns 40 may each have a neck portion extending in the first direction (e.g., the x-axis direction) and a head portion at the end of the neck portion. For example, each of the first infiltration barrier pattern 41 and the second infiltration barrier pattern 42 may have the neck portion and the head portion described above. The neck portion may be integrally formed with the head portion. In an embodiment, the head portions of the infiltration barrier patterns 40 may each have a generally circular shape. In an embodiment, the neck portion of each infiltration barrier pattern 40 may vary in width along the first direction (e.g., the x-axis direction). However, embodiments are not limited to the specific shapes of the infiltration barrier patterns 40, and the shapes of the infiltration barrier patterns 40 may vary.

The infiltration barrier patterns 40 may prevent foreign materials (e.g., moisture) that have infiltrated the display device 2 from further infiltrating towards the display area DA (see, e.g., FIG. 2). For example, the infiltration barrier patterns 40 may directly block the foreign materials while the foreign materials move (e.g., flow) in the +y direction in which the display area DA is located. Alternatively, the infiltration barrier patterns 40 may extend the infiltration path of the foreign materials by causing the foreign materials, which move (e.g., flow) in the +y direction, to bypass the infiltration barrier patterns 40, thereby delaying the infiltration of the foreign materials.

The dam patterns 50 may not only protect the infiltration barrier patterns 40 but may also prevent the overflow of a layer having fluidity that is arranged on the display device 2.

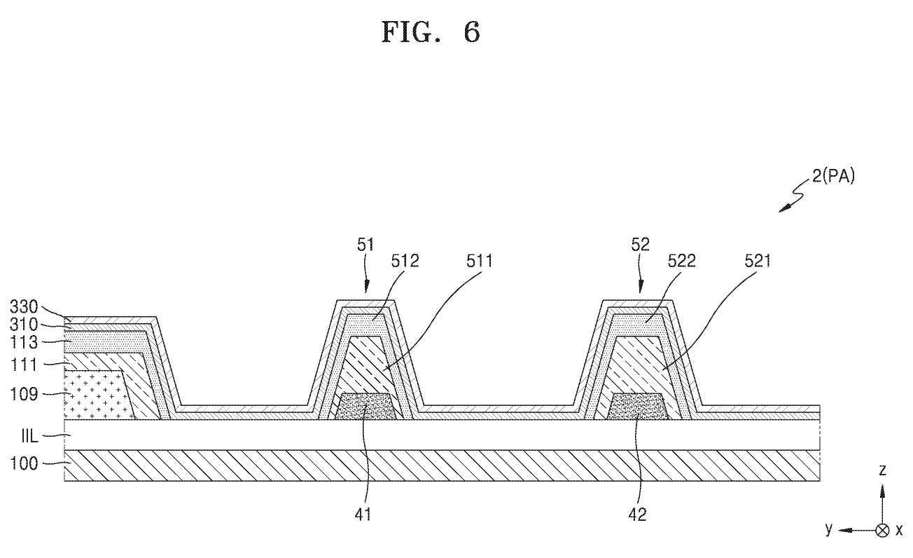

FIG. 6 is a schematic cross-sectional view of a portion of the display device 2 according to an embodiment. FIG. 6 is a cross-sectional view of the display device 2 taken along the line V-V' in FIG. 5.

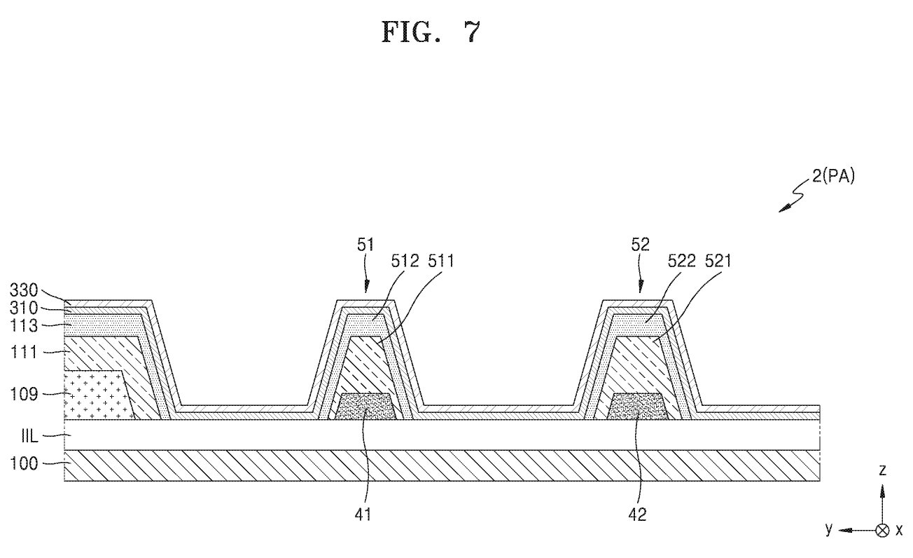

FIG. 7 is a schematic cross-sectional view of a portion of the display device 2 according to an embodiment. FIG. 7 is a cross-sectional view of the display device 2 taken along the line V-V' in FIG. 5 according to another embodiment.

Referring to FIGS. 6 and 7, the first infiltration barrier pattern 41 and the second infiltration barrier pattern 42 may be arranged on the inorganic insulating layer IIL. In other words, the inorganic insulating layer IIL may be arranged between the first infiltration barrier pattern 41 and the substrate 100 and between the second infiltration barrier pattern 42 and the substrate 100.

The first infiltration barrier pattern 41 and the second infiltration barrier pattern 42 may be arranged on the same layer as the contact metal 110 described above with reference to FIG. 4A. In an embodiment, the first infiltration barrier pattern 41, the second infiltration barrier pattern 42, and the contact metal 110 may be formed through the same process. The contact metal 110 may be arranged on the first organic insulating layer 109. In the peripheral area PA, a portion of the first organic insulating layer 109 may not extend to the region where the first infiltration barrier pattern 41 or the second infiltration barrier pattern 42 is arranged. Therefore, the first infiltration barrier pattern 41 and the second infiltration barrier pattern 42 may not be arranged on the first organic insulating layer 109 but may be arranged on the inorganic insulating layer IIL.

The first dam pattern 51 may be arranged on the first infiltration barrier pattern 41 and may entirely cover the same. For example, the first dam pattern 51 may cover both the upper surface and the side surfaces of the first infiltration barrier pattern 41. The second dam pattern 52 may be arranged on the second infiltration barrier pattern 42 and may entirely cover the same. For example, the second dam pattern 52 may cover both the upper surface and the side surfaces of the second infiltration barrier pattern 42.

The first dam pattern 51 may include a 1-1st layer 511 and a 1-2nd layer 512. The 1-1st layer 511 may be arranged on the first infiltration barrier pattern 41. In an embodiment, the 1-1st layer 511 may cover the upper surface and the side surface of the first infiltration barrier pattern 41. The 1-2nd layer 512 may be arranged on the 1-1st layer 511. In an embodiment, the 1-2nd layer 512 may cover the upper surface and the side surfaces of the 1-1st layer 511.

The second dam pattern 52 may include a 2-1st layer 521 and a 2-2nd layer 522. The 2-1st layer 521 may be arranged on the second infiltration barrier pattern 42. In an embodiment, the 2-1st layer 521 may cover the upper surface and the side surfaces of the second infiltration barrier pattern 42. The 2-2nd layer 522 may be arranged on the 2-1st layer 521. In an embodiment, the 2-2nd layer 522 may cover the upper surface and the side surfaces of the 2-1st layer 521.

In an embodiment, the 1-1st layer 511 and the 2-1st layer 521 may be arranged on the same layer. In an embodiment, the 1-1st layer 511, the 2-1st layer 521, and the second organic insulating layer 111 may be arranged on the same layer. In an embodiment, the 1-1st layer 511, the 2-1st layer 521, and the second organic insulating layer 111 may be formed through the same process. In an embodiment, the 1-1st layer 511 and/or the 2-1st layer 521 may include the same material as the second organic insulating layer 111. Therefore, the 1-1st layer 511 and/or the 2-1st layer 521 may be an organic layer that includes an organic insulating material.

In an embodiment, the 1-1st layer 511 and the 2-1st layer 521 may be formed through the same process as the second organic insulating layer 111, but may be formed to have a greater thickness (or height) than the second organic insulating layer 111 to ensure that the first dam pattern 51 and the second dam pattern 52 have sufficient thickness (e.g., height in the z direction). For example, as shown in FIG. 6, the upper surface of each of the 1-1st layer 511 and the 2-1st layer 521 may be at a higher level than the upper surface of the second organic insulating layer 111 (e.g., in the +z direction). For example, the thickness of the 1-1st layer 511 and the thickness of the 2-1st layer 521 may be, for example, greater than that of the second organic insulating layer 111.

However, embodiments are not limited thereto. In another embodiment, as shown in FIG. 7, the upper surface of each of the 1-1st layer 511 and the 2-1st layer 521 may be at substantially the same level as the upper surface of the second organic insulating layer 111. For example, the thicknesses of the 1-1st layer 511, the 2-1st layer 521, and the second organic insulating layer 111 may be substantially the same as each other.

In an embodiment, the 1-2nd layer 512 and the 2-2nd layer 522 may be arranged on the same layer. In an embodiment, the 1-2nd layer 512, the 2-2nd layer 522, and the pixel-defining layer 113 may be arranged on the same layer. In an embodiment, the 1-2nd layer 512, the 2-2nd layer 522, and the pixel-defining layer 113 may be formed through the same process. In an embodiment, the 1-2nd layer 512 and/or the 2-2nd layer 522 may include the same material as the pixel-defining layer 113. Therefore, the 1-2nd layer 512 and/or the 2-2nd layer 522 may be an organic layer including an organic insulating material.

The first inorganic encapsulation layer 310 and the second inorganic encapsulation layer 330 may be arranged on the first dam pattern 51 and the second dam pattern 52. The first inorganic encapsulation layer 310 may entirely cover the first dam pattern 51 and the second dam pattern 52. For example, the first inorganic encapsulation layer 310 may entirely cover the 1-2nd layer 512 and the 2-2nd layer 522. The second inorganic encapsulation layer 330 may be arranged on the first inorganic encapsulation layer 310.

The first inorganic encapsulation layer 310 may be spaced apart from the first infiltration barrier pattern 41 by the first dam pattern 51. In other words, the 1-1st layer 511 and the 1-2nd layer 512 may be between the first inorganic encapsulation layer 310 and the first infiltration barrier pattern 41. The first inorganic encapsulation layer 310 may be spaced apart from the second infiltration barrier pattern 42 by the second dam pattern 52. In other words, the 2-1st layer 521 and the 2-2nd layer 522 may be between the first inorganic encapsulation layer 310 and the second infiltration barrier pattern 42.

The first inorganic encapsulation layer 310 may directly contact the inorganic insulating layer IIL in a region that does not overlap (e.g., a region offset from) the first dam pattern 51 and/or the second dam pattern 52. In an embodiment, the first inorganic encapsulation layer 310 may directly contact the inorganic insulating layer IIL in a region between the first dam pattern 51 and the second dam pattern 52. In an embodiment, the first inorganic encapsulation layer 310 may directly contact the inorganic insulating layer IIL in a portion (e.g., at an area) between the first dam pattern 51 and the pixel-defining layer 113.

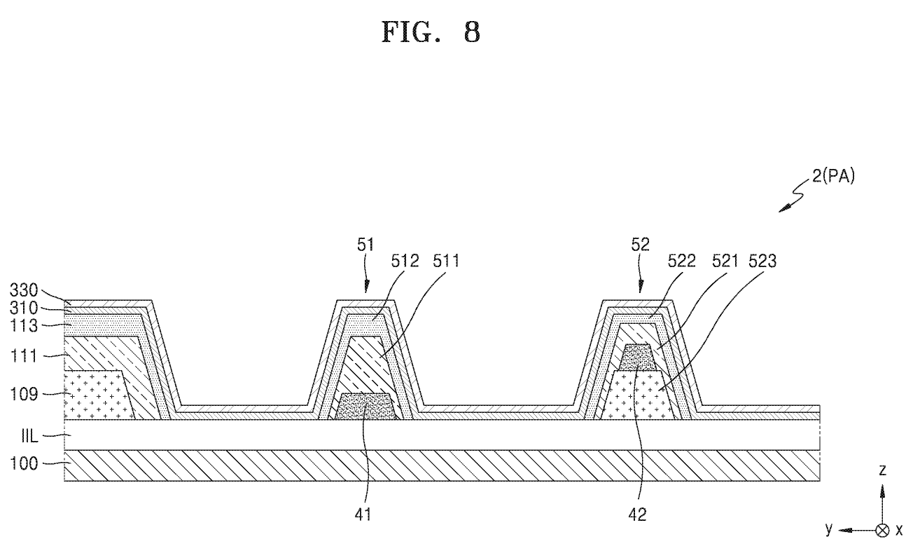

FIG. 8 is a schematic cross-sectional view of a portion of the display device 2 according to an embodiment. FIG. 8 is a cross-sectional view of the display device 2 taken along the line V-V' in FIG. 5 according to another embodiment.

Referring to FIG. 8, the second dam pattern 52 may further include a 2-3rd layer 523. The 2-3rd layer 523 may be arranged under the second infiltration barrier pattern 42. For example, the 2-3rd layer 523 may be between the second infiltration barrier pattern 42 and the inorganic insulating layer IIL. The second infiltration barrier pattern 42 may be arranged on the 2-3rd layer 523 and cover at least a portion of the upper surface (e.g., the entire upper surface) of the 2-3rd layer 523. FIG. 8 illustrates an embodiment in which the second infiltration barrier pattern 42 covers a portion of the upper surface of the 2-3rd layer 523. The 2-1st layer 521 may cover the side surfaces of the 2-3rd layer 523.

In an embodiment, the 2-3rd layer 523 may be arranged on the same layer as the first organic insulating layer 109. In an embodiment, the 2-3rd layer 523 and the first organic insulating layer 109 may be formed through the same process. In an embodiment, the 2-3rd layer 523 may include the same material as the first organic insulating layer 109. Therefore, the 2-3rd layer 523 may be an organic layer including an organic insulating material. For example, the second dam pattern 52 may include an organic layer (e.g., the 2-3rd layer 523) arranged under the second infiltration barrier pattern 42.

FIG. 8 illustrates an embodiment in which the second dam pattern 52 includes an additional layer (e.g., the 2-3rd layer 523) arranged on the same layer as the first organic insulating layer 109. In another embodiment, the first dam pattern 51 may include an additional layer (e.g., the 1-3rd layer) arranged on the same layer as the first organic insulating layer 109. In another embodiment, both the first dam pattern 51 and the second dam pattern 52 may include additional layers (e.g., a 1-3rd layer and the 2-3rd layer 523) arranged on the same layer as the first organic insulating layer 109.

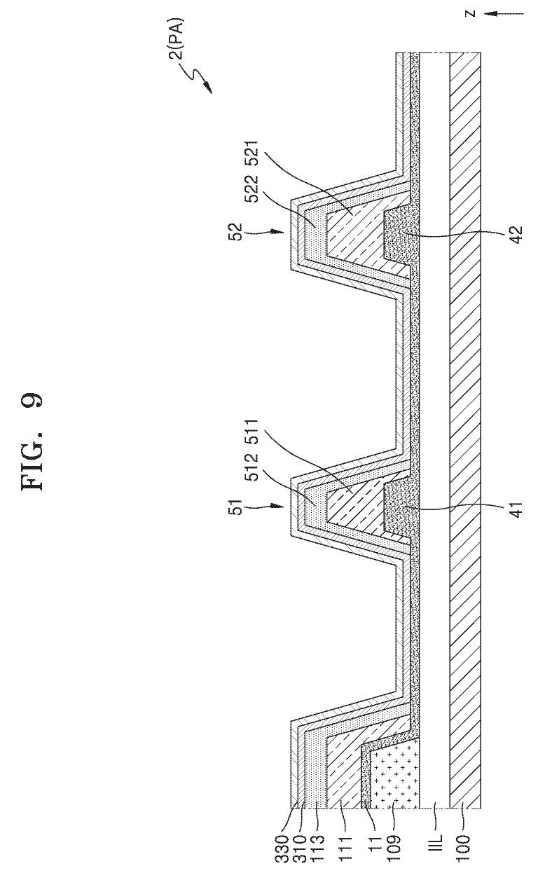

FIG. 9 is a schematic cross-sectional view of a portion of the display device 2 according to an embodiment.

Referring to FIG. 9, the shape of the driving voltage supply line 11 may be compared with those of the first infiltration barrier pattern 41 and the second infiltration barrier pattern 42.

In an embodiment, the driving voltage supply line 11, the first infiltration barrier pattern 41, and the second infiltration barrier pattern 42 may be arranged on the same layer. In an embodiment, the driving voltage supply line 11, the first infiltration barrier pattern 41, the second infiltration barrier pattern 42, and the contact metal 110 (see, e.g., FIG. 4A) may be arranged on the same layer. In an embodiment, the driving voltage supply line 11, the first infiltration barrier pattern 41, the second infiltration barrier pattern 42, and the contact metal 110 may be formed through the same process.

In an embodiment, the first infiltration barrier pattern 41 may be shaped such that a portion of the driving voltage supply line 11 protrudes in the third direction (e.g., the z-axis direction). For example, the driving voltage supply line 11 may have a greater thickness at the first infiltration barrier pattern 41 than at other portions. In an embodiment, the second infiltration barrier pattern 42 may be shaped such that a portion of the driving voltage supply line 11 protrudes in the third direction (e.g., the z-axis direction). For example, the driving voltage supply line 11 may have a greater thickness at the second infiltration barrier pattern 42 than at other portions.

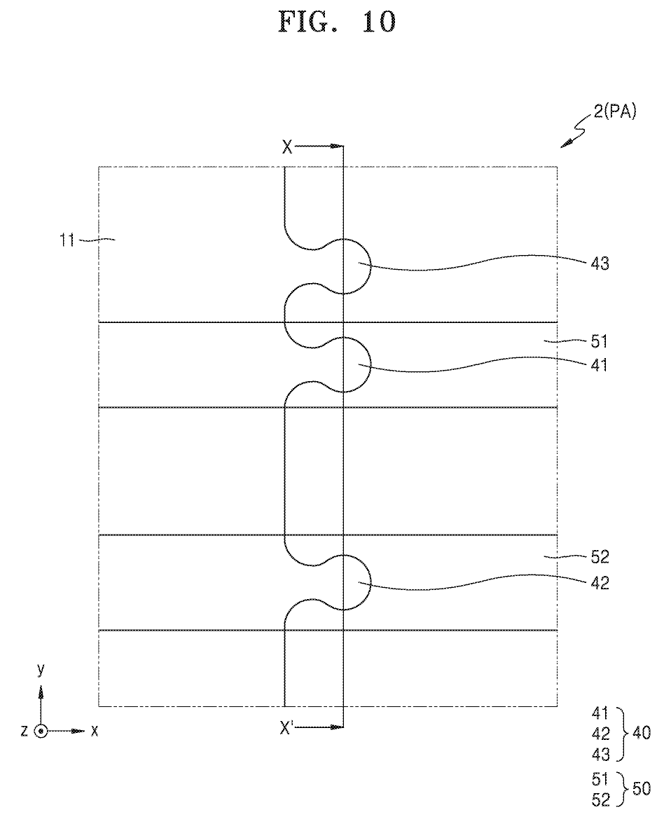

FIG. 10 is a schematic plan view of a portion of the peripheral area PA of the display device 2 according to an embodiment.

Referring to FIG. 10, the infiltration barrier patterns 40 may further include a third infiltration barrier pattern 43. The third infiltration barrier pattern 43 may be arranged in the +y direction from the first infiltration barrier pattern 41. A separate dam pattern overlapping the third infiltration barrier pattern 43 may not be additionally provided. However, as described below, the third infiltration barrier pattern 43 may be covered by an organic layer. The third infiltration barrier pattern 43 may be spaced apart from the first infiltration barrier pattern 41.

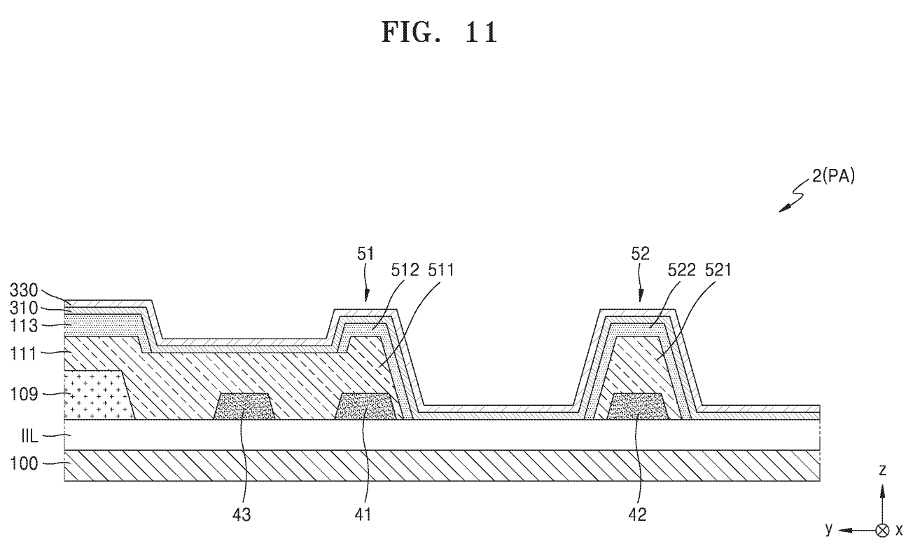

FIG. 11 is a schematic cross-sectional view of a portion of the display device 2 according to an embodiment. FIG. 11 is a cross-sectional view of the display device 2 taken along the line X-X' in FIG. 10.

Referring to FIG. 11, the 1-1st layer 511 of the first dam pattern 51 may be connected to the second organic insulating layer 111. For example, the 1-1st layer 511 of the first dam pattern 51 may be formed integrally with the second organic insulating layer 111.

In an embodiment, the 1-1st layer 511 of the first dam pattern 51 may extend towards the display area DA (see, e.g,. FIG. 2) over the peripheral area PA, and a corresponding portion of the 1-1st layer 511 may correspond to the second organic insulating layer 111 or may be connected thereto. From another perspective, a portion of the second organic insulating layer 111 may extend to the peripheral area PA to overlap the first infiltration barrier pattern 41, and a portion of the second organic insulating layer 111 that overlaps the first infiltration barrier pattern 41 may be understood as the 1-1st layer 511 of the first dam pattern 51.

The third infiltration barrier pattern 43 may be arranged between the first infiltration barrier pattern 41 and the first organic insulating layer 109. The third infiltration barrier pattern 43 may be arranged on the inorganic insulating layer IIL. In an embodiment, the first infiltration barrier pattern 41, the second infiltration barrier pattern 42, and the third infiltration barrier pattern 43 may be arranged on the same layer. In an embodiment, the first infiltration barrier pattern 41, the second infiltration barrier pattern 42, and the third infiltration barrier pattern 43 may be formed through the same process.

The third infiltration barrier pattern 43 may be covered by the second organic insulating layer 111. For example, the second organic insulating layer 111 may be formed integrally with the 1-1st layer 511 of the first dam pattern 51, and the third infiltration barrier pattern 43 may be arranged under the integrated structure. When the second organic insulating layer 111 is understood as a portion at where the 1-1st layer 511 of the first dam pattern 51 extends, it may be understood that the 1-1st layer 511 covers at least two infiltration barrier patterns, for example, the first infiltration barrier pattern 41 and the third infiltration barrier pattern 43.

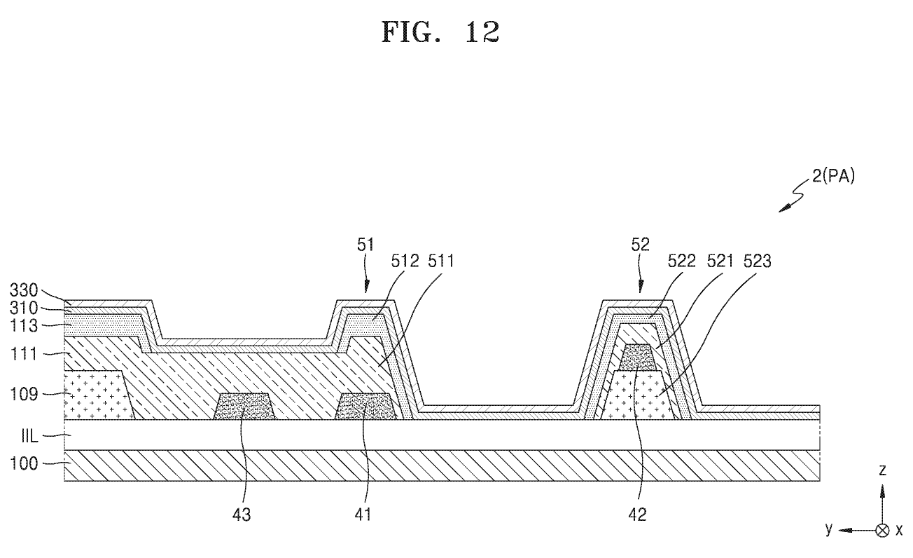

FIG. 12 is a schematic cross-sectional view of a portion of the display device 2 according to an embodiment. FIG. 12 is a cross-sectional view of the display device 2 taken along the line X-X' in FIG. 10 according to another embodiment.

Referring to FIG. 12, the second dam pattern 52 may further include the 2-3rd layer 523. The 2-3rd layer 523 may be arranged under the second infiltration barrier pattern 42. For example, the 2-3rd layer 523 may be between the second infiltration barrier pattern 42 and the inorganic insulating layer IIL. The second infiltration barrier pattern 42 may be arranged on the 2-3rd layer 523 and may cover at least a portion of the upper surface (e.g., the entire upper surface) of the 2-3rd layer 523. FIG. 12 illustrates an embodiment in which the second infiltration barrier pattern 42 covers a portion of the upper surface of the 2-3rd layer 523. The 2-1st layer 521 may cover the side surfaces of the 2-3rd layer 523.

In an embodiment, the 2-3rd layer 523 may be arranged on the same layer as the first organic insulating layer 109. In an embodiment, the 2-3rd layer 523 and the first organic insulating layer 109 may be formed through the same process. In an embodiment, the 2-3rd layer 523 may include the same material as the first organic insulating layer 109. Therefore, the 2-3rd layer 523 may be an organic layer including an organic insulating material. For example, the second dam pattern 52 may include an organic layer (e.g., the 2-3rd layer 523) arranged under the second infiltration barrier pattern 42.

FIG. 12 illustrates an embodiment in which the second dam pattern 52 includes an additional layer (e.g., the 2-3rd layer 523) arranged on the same layer as the first organic insulating layer 109. In another embodiment, the first dam pattern 51 may include an additional layer (e.g., the 1-3rd layer) arranged on the same layer as the first organic insulating layer 109. In another embodiment, both the first dam pattern 51 and the second dam pattern 52 may include additional layers (e.g., the 1-3rd layer and the 2-3rd layer 523) arranged on the same layer as the first organic insulating layer 109.

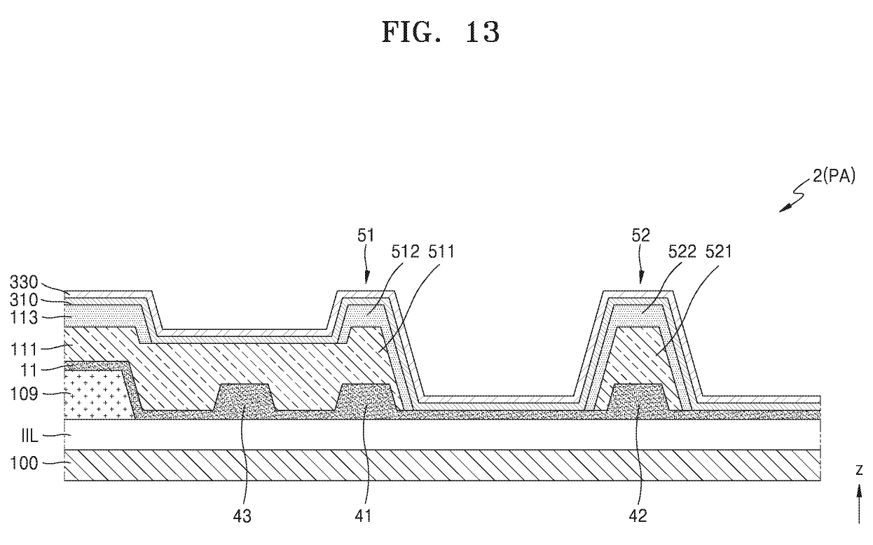

FIG. 13 is a schematic cross-sectional view of a portion of the display device 2 according to an embodiment.

Referring to FIG. 13, the shape of the driving voltage supply line 11 may be compared with those of the first infiltration barrier pattern 41 to the third infiltration barrier pattern 43.

In an embodiment, the driving voltage supply line 11, the first infiltration barrier pattern 41, the second infiltration barrier pattern 42, and the third infiltration barrier pattern 43 may be arranged on the same layer. In an embodiment, the driving voltage supply line 11, the first infiltration barrier pattern 41, the second infiltration barrier pattern 42, the third infiltration barrier pattern 43, and the contact metal 110 (see, e.g., FIG. 4A) may be arranged on the same layer. In an embodiment, the driving voltage supply line 11, the first infiltration barrier pattern 41, the second infiltration barrier pattern 42, the third infiltration barrier pattern 43, and the contact metal 110 may be formed through the same process.

In an embodiment, the first infiltration barrier pattern 41 may be shaped such that a portion of the driving voltage supply line 11 protrudes in the third direction (e.g., the z-axis direction). For example, the driving voltage supply line 11 may have a greater thickness at the first infiltration barrier pattern 41 than at other portions. In an embodiment, the second infiltration barrier pattern 42 may be shaped such that a portion of the driving voltage supply line 11 protrudes in the third direction (e.g., the z-axis direction). For example, the driving voltage supply line 11 may have a greater thickness at the second infiltration barrier pattern 42 than at other portions. In an embodiment, the third infiltration barrier pattern 43 may be shaped such that a portion of the driving voltage supply line 11 protrudes in the third direction (e.g., the z-axis direction). For example, the driving voltage supply line 11 may have a greater thickness at the third infiltration barrier pattern 43 than at other portions.

However, the present disclosure is not limited to the embodiments described with reference to FIGS. 5 to 13, and any structure in which the infiltration barrier patterns 40 are covered by an organic layer (e.g., the dam patterns 50) may fall within the scope of the present disclosure.

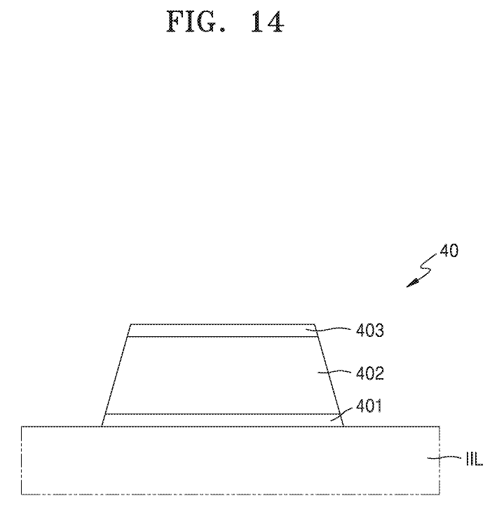

FIG. 14 is a schematic cross-sectional view illustrating one of the infiltration barrier patterns 40 according to an embodiment.

Referring to FIG. 14, at least one of the infiltration barrier patterns 40 may include a first layer 401, a second layer 402, and a third layer 403. The first layer 401, the second layer 402, and the third layer 403 may each include a conductive material, for example, metal. At least one of the first layer 401, the second layer 402, and the third layer 403 may include a material that is different from that of another. In an embodiment, the first layer 401 and the third layer 403 may include the same material, and the second layer 402 may include a different material therefrom. For example, the first layer 401 and the third layer 403 may include Ti, and the second layer 402 may include Al.

In an embodiment, at least one of the first layer 401, the second layer 402, and the third layer 403 may include a material having a different etch selectivity from that of another. For example, the first layer 401 and the third layer 403 may include Ti, the second layer 402 may include Al, and Ti and Al may have different etch selectivities.

In the structure in which the infiltration barrier patterns 40 are not covered by an organic layer, some of the first layer 401, the second layer 402, and the third layer 403 may be unintendedly etched during the process of etching other layers. In this case, some of the first layer 401, the second layer 402, and the third layer 403 may have an undercut structure or tip structure. For example, during the process of etching other layers, a portion of the second layer 402 may be unintendedly etched. As a result, an undercut (or tip) structure in which an edge of the third layer 403 protrudes beyond the side surface of the second layer 402 may be formed. Such an undercut structure may cause cracks or seams in other layers arranged on the infiltration barrier patterns 40.

In the above-described structure in which the infiltration barrier patterns 40 are covered by an organic layer, unintended etching of some of the first layer 401, the second layer 402, and the third layer 403 may be prevented. Accordingly, an undercut structure or a tip structure may not be formed. For example, the side surfaces of the first layer 401, the second layer 402, and the third layer 403 may be placed on the same plane. As a result, the occurrence of cracks or seams in other layers arranged on the infiltration barrier patterns 40 may be prevented (or at least reduced).

The display device described above may include infiltration barrier patterns and, thus, may prevent the infiltration of foreign materials (e.g., moisture). In addition, because the infiltration barrier patterns are arranged under a dam structure including an organic layer, cracks in an inorganic layer generated by step differences of the infiltration barrier patterns may be reduced or prevented, and thus, the infiltration barrier effect may be further enhanced. However, aspects and features of the present disclosure not intended to limit thereto.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display device comprising:
a substrate having a display area and a peripheral area;
a light-emitting diode on the substrate in the display area;
a first infiltration barrier pattern on the substrate in the peripheral area; and
a first dam pattern on the first infiltration barrier pattern, the first dam pattern comprising an organic layer covering the first infiltration barrier pattern.

2. The display device of claim 1, further comprising:
a second infiltration barrier pattern on the substrate and spaced apart from the first infiltration barrier pattern; and
a second dam pattern covering the second infiltration barrier pattern.

3. The display device of claim 2, further comprising:
an inorganic insulating layer between the first infiltration barrier pattern and the substrate; and
an encapsulation layer arranged on the first dam pattern,
wherein the encapsulation layer is spaced apart from the first infiltration barrier pattern and the second infiltration barrier pattern.

4. The display device of claim 3, wherein the encapsulation layer directly contacts the inorganic insulating layer in a region between the first dam pattern and the second dam pattern.

5. The display device of claim 2, wherein the second dam pattern comprises an organic layer under the second infiltration barrier pattern.

6. The display device of claim 1, further comprising a third infiltration barrier pattern,
wherein the organic layer of the first dam pattern extends to the display area, and
wherein the third infiltration barrier pattern is under the organic layer and spaced apart from the first infiltration barrier pattern.

7. The display device of claim 1, wherein the first infiltration barrier pattern comprises a first layer, a second layer on the first layer, and a third layer on the second layer, and
wherein at least one of the first layer, the second layer, and the third layer comprises a material that is different from that of another one of the first layer, the second layer, and the third layer.

8. The display device of claim 7, wherein a side surface of the second layer is on a same plane as a side surface of the third layer.

9. The display device of claim 1, further comprising a voltage supply line extending in a first direction and configured to supply a voltage to the light-emitting diode,
wherein the first infiltration barrier pattern is a portion of the voltage supply line protruding in a second direction crossing the first direction.

10. The display device of claim 9, wherein the first dam pattern extends in the second direction.

11. A display device comprising:
a substrate having a display area and a peripheral area;
an inorganic insulating layer on the substrate;
a plurality of infiltration barrier patterns on the inorganic insulating layer in the peripheral area;
a plurality of dam patterns covering the plurality of infiltration barrier patterns; and
an encapsulation layer arranged on the plurality of dam patterns, the encapsulation layer directly contacting the inorganic insulating layer between two adjacent ones of the plurality of dam patterns.

12. The display device of claim 11, wherein the encapsulation layer is spaced apart from the plurality of infiltration barrier patterns.

13. The display device of claim 11, wherein the plurality of dam patterns comprise organic layers covering the plurality of infiltration barrier patterns, respectively.

14. The display device of claim 13, wherein the organic layer of one of the plurality of dam patterns covers two or more of the plurality of infiltration barrier patterns.

15. The display device of claim 11, wherein one of the plurality of dam patterns comprises an organic layer under an infiltration barrier pattern corresponding to the one of the plurality of dam patterns.

16. The display device of claim 11, wherein one of the plurality of infiltration barrier patterns comprises a first layer, a second layer on the first layer, and a third layer on the second layer, and
wherein at least one of the first layer, the second layer, and the third layer comprises a material that is different from that of another one of the first layer, the second layer, and the third layer.

17. The display device of claim 16, wherein a side surface of the second layer is on a same plane as a side surface of the third layer.

18. An electronic device comprising a display device and a housing accommodating the display device,
wherein the display device comprises:
a substrate having a display area and a peripheral area;
a light-emitting diode on the substrate in the display area;
a first infiltration barrier pattern on the substrate in the peripheral area; and
a first dam pattern on the first infiltration barrier pattern, the first dam pattern comprising an organic layer covering the first infiltration barrier pattern.

19. The electronic device of claim 18, further comprising:
a second infiltration barrier pattern on the substrate and spaced apart from the first infiltration barrier pattern;
a second dam pattern covering the second infiltration barrier pattern;
an inorganic insulating layer under the first infiltration barrier pattern and the second infiltration barrier pattern and on the substrate; and
an encapsulation layer on the first dam pattern and the second dam pattern, the encapsulation layer being spaced apart from the first infiltration barrier pattern and the second infiltration barrier pattern.

20. The electronic device of claim 18, further comprising a voltage supply line extending in a first direction and configured to supply a voltage to the light-emitting diode,
wherein the first infiltration barrier pattern is a portion of the voltage supply line protruding in a second direction crossing the first direction.
